(19) United States
(12) Patent Application Publication
(10) Pub. No.: US 2022/0180494 A1
(43) Pub. Date: Jun. 9, 2022

(54) WIRE SHAPE MEASUREMENT DEVICE, WIRE THREE-DIMENSIONAL IMAGE GENERATION METHOD, AND WIRE SHAPE MEASUREMENT METHOD

(71) Applicant: SHINKAWA LTD., Tokyo (JP)

(72) Inventors: Takaya KINJO, Tokyo (JP); Shota NAKANO, Tokyo (JP); Akira SEKIKAWA, Tokyo (JP); Hiroshi MUNAKATA, Tokyo (JP)

(73) Assignee: SHINKAWA LTD., Tokyo (JP)

(21) Appl. No.: 17/605,225

(22) PCT Filed: Apr. 7, 2020
(86) PCT No.: PCT/JP2020/015653

§ 371 Date: Oct. 20, 2021

(30) Foreign Application Priority Data
Apr. 22, 2019 (JP) 2019-081252

(51) Int. Cl. G06T 7/00; H04N 13/156; G06T 7/55; G06T 7/62; G06T 7/70; H04N 5/247; H01L 23/00

(52) U.S. Cl. CPC G06T 7/001; H04N 13/156; G06T 7/55; G06T 7/62; G06T 7/70; H01L 2224/4809; H01L 24/48; G06T 2207/30148; G06T 2207/30244; G06T 2200/04; H04N 5/247

(57) ABSTRACT

Provided is a wire shape measurement device of a semiconductor device comprising a substrate, a semiconductor element, and a wire connecting an electrode of the semiconductor element to an electrode of the substrate. The wire shape measurement device comprises: cameras that capture two-dimensional images of the semiconductor device; and a control unit that examines the shape of the wire based on the two-dimensional images of the semiconductor device acquired by the cameras. The control unit performs pattern matching using information on the position at which the wire is connected to the substrate or the semiconductor element and thickness information of the wire, and by utilizing the pattern matching, the control unit: generates a three-dimensional image of the wire from the two-dimensional images of the semiconductor device acquired by the cameras; and performs shape measurement of the wire based on the generated three-dimensional image of the wire.

### BACKGROUND

### Technical Field

The present invention relates to a wire shape measurement device for measuring a shape of a wire that connects an electrode of a semiconductor element mounted on a substrate and an electrode of the substrate, a method for generating a three-dimensional image of the wire, and a wire shape measurement method for measuring a wire shape.

### Description of Related Art

A loop shape of a bonding wire (hereinafter referred to as wire) that connects a pad of a semiconductor chip and a lead of a substrate is measured. A method of detecting XY coordinates of the wire at a focusing height of an optical system to measure a three-dimensional shape of the entire wire has been proposed as a method for measuring the loop shape of the wire (see, for example, Patent Document 1).

This method illuminates the wire with a ring-shaped illuminator, captures wire images while changing the focusing height using the optical system with a shallow depth of focus, and detects a dark part that appears in the center of each wire image, so as to detect the XY coordinates of the wire at each focusing height and detect the three-dimensional shape of the entire wire from the data.

### RELATED ART

### Patent Document

[Patent Document 1] Specification of Japanese Patent No. 3235009

### SUMMARY

### Problems to be Solved

In recent years, there has been a demand for measuring the shapes of all the wires connecting the electrode of the semiconductor chip and the electrode of the substrate. However, according to the wire shape measurement method described in Patent Document 1, it is necessary to capture a plurality of images by changing the focusing height of the optical system, and therefore the time required for the inspection is long.

Further, it is also required to improve the accuracy of wire shape measurement. When the wire is illuminated with a ring-shaped illuminator as in the conventional technology described in Patent Document 1, in the portion where the wire extends in the substantially horizontal direction in the image, the vicinity of the center line of the wire at the focal point is dark and the edges at both ends of the wire in the width direction are bright, but in the portion where the wire is inclined, the vicinity of the center line of the wire may be bright and the edges at both ends of the wire in the width direction may be dark. Therefore, in the conventional technology described in Patent Document 1, the detection accuracy of the three-dimensional shape of the entire wire may decrease for a wire having an inclined portion.

The present invention is to provide a wire shape measurement device that is capable of measuring a shape of a wire with high accuracy in a short time.

### Means for Solving the Problems

A wire shape measurement device according to the present invention is for a semiconductor device, which includes: a substrate; a semiconductor element mounted on the substrate; and a wire connecting an electrode of the semiconductor element and an electrode of the substrate, or connecting one electrode of the semiconductor element and another electrode of the semiconductor element. The wire shape measurement device includes: a plurality of cameras capturing two-dimensional images of the semiconductor device; and a control unit measuring a shape of the wire based on the two-dimensional images of the semiconductor device acquired by the cameras. The control unit: generates a three-dimensional image of the wire from the two-dimensional images of the semiconductor device acquired by the cameras by pattern matching using connection position information of a position where the wire is connected to the substrate or the semiconductor element and thickness information of the wire, and measures the shape of the wire based on the three-dimensional image of the wire generated.

Since the three-dimensional image of the wire is generated from the two-dimensional images of the semiconductor device acquired by the cameras by pattern matching using the connection position information of the position where the wire is connected to the substrate or the semiconductor element and the thickness information of the wire, the three-dimensional image can be generated accurately in a short time. Thereby, the wire shape measurement device capable of measuring the shape of the wire with high accuracy in a short time can be provided.

In the wire shape measurement device according to the present invention, the control unit may respectively extract two-dimensional coordinates of each point in each two-dimensional image corresponding to one portion of the wire from the two-dimensional images of the semiconductor device acquired by the cameras by using the connection position information of the position where the wire is connected to the substrate or the semiconductor element and the thickness information of the wire, calculate three-dimensional coordinates of one portion of the wire by using the two-dimensional coordinates extracted, and generate a three-dimensional image of the wire based on the three-dimensional coordinates calculated.

Further, in the wire shape measurement device according to the present invention, the control unit may repeatedly respectively extract two-dimensional coordinates of each point in each two-dimensional image corresponding to one portion of the wire from the two-dimensional images of the semiconductor device acquired by the cameras by using the connection position information of the position where the wire is connected to the substrate or the semiconductor element and the thickness information of the wire from a start end to a terminal end of the wire, to extract the two-dimensional coordinates of each point in each two-dimensional image respectively corresponding to a plurality of portions of the wire, calculate three-dimensional coordinates of the plurality of portions of the wire by using the two-dimensional coordinates in each two-dimensional image respectively corresponding to the plurality of portions of the wire extracted, and generate a three-dimensional image from the start end to the terminal end of the wire based on the three-dimensional coordinates of the plurality of portions of the wire calculated.

Since the image of the wire is specified from the two-dimensional images of the entire semiconductor device captured by the cameras using the connection position information of the position where the wire is connected to the substrate or the semiconductor element and the thickness information of the wire, and the two-dimensional coordinates of the point on the wire image are extracted, the two-dimensional coordinates of the point on the image of the wire can be extracted from the two-dimensional images of the entire semiconductor device in a short time. Thereby, the wire shape measurement device capable of measuring the shape of the wire with high accuracy in a short time can be provided.

In the wire shape measurement device according to the present invention, the cameras may be respectively arranged on both sides of the wire so that optical axes of the cameras intersect a direction in which the wire extends.

By arranging the cameras in this way, the difference in the two-dimensional coordinates of each point in each two-dimensional image corresponding to one portion of the wire captured by each camera becomes large, the three-dimensional coordinates of one portion of the wire can be calculated with high accuracy, and the accuracy of measuring the shape of the wire can be improved.

In the wire shape measurement device according to the present invention, the control unit may inspect the shape of the wire based on the three-dimensional image of the wire generated, the control unit may inspect the shape of the wire by comparing the three-dimensional image of the wire generated with a reference shape of the wire, and the control unit may extract a shape parameter of the wire from the three-dimensional image of the wire generated, and inspect the shape of the wire by comparing the shape parameter extracted with a reference value of the shape parameter.

Thereby, it is possible to perform various shape measurements and shape inspections on the wire.

A wire three-dimensional image generation method according to the present invention is for a semiconductor device, which includes: a substrate; a semiconductor element mounted on the substrate; and a wire connecting an electrode of the semiconductor element and an electrode of the substrate, or connecting one electrode of the semiconductor element and another electrode of the semiconductor element. The wire three-dimensional image generation method includes: an image capturing step of respectively capturing two-dimensional images of the semiconductor device with a plurality of cameras; and a three-dimensional image generation step of generating a three-dimensional image of the wire from the two-dimensional images of the semiconductor device acquired by the cameras by pattern matching using connection position information of a position where the wire is connected to the substrate or the semiconductor element and thickness information of the wire.

Since the three-dimensional image of the wire is generated from the two-dimensional images of the semiconductor device acquired by the cameras by pattern matching using the connection position information of the position where the wire is connected to the substrate or the semiconductor element and the thickness information of the wire, the three-dimensional image can be generated accurately in a short time.

In the wire three-dimensional image generation method according to the present invention, the three-dimensional image generation step may include: a two-dimensional coordinate extraction step of respectively extracting two-dimensional coordinates of each point in each two-dimensional image corresponding to one portion of the wire from the two-dimensional images of the semiconductor device acquired by the cameras by using the connection position information of the position where the wire is connected to the substrate or the semiconductor element and the thickness information of the wire; a three-dimensional coordinate calculation step of calculating three-dimensional coordinates of one portion of the wire by using the two-dimensional coordinates extracted; and an image generation step of generating a three-dimensional image of the wire based on the three-dimensional coordinates calculated.

Further, in the wire three-dimensional image generation method according to the present invention, the two-dimensional coordinate extraction step may repeatedly respectively extract two-dimensional coordinates of each point in each two-dimensional image corresponding to one portion of the wire from the two-dimensional images of the semiconductor device acquired by the cameras by using the connection position information of the position where the wire is connected to the substrate or the semiconductor element and the thickness information of the wire from a start end to a terminal end of the wire, to extract the two-dimensional coordinates of each point in each two-dimensional image respectively corresponding to a plurality of portions of the wire. The three-dimensional coordinate calculation step may calculate three-dimensional coordinates of the plurality of portions of the wire by using the two-dimensional coordinates in each two-dimensional image respectively corresponding to the plurality of portions of the wire extracted. The image generation step may generate a three-dimensional image from the start end to the terminal end of the wire based on the three-dimensional coordinates of the plurality of portions of the wire calculated.

Since the image of the wire is specified from the two-dimensional images of the entire semiconductor device captured by the cameras using the connection position information of the position where the wire is connected to the substrate or the semiconductor element and the thickness information of the wire, and the two-dimensional coordinates of the point on the wire image are extracted, the two-dimensional coordinates of the point on the image of the wire can be extracted from the two-dimensional images of the entire semiconductor device in a short time.

A wire shape measurement method according to the present invention is for a semiconductor device, which includes: a substrate; a semiconductor element mounted on the substrate; and a wire connecting an electrode of the semiconductor element and an electrode of the substrate, or connecting one electrode of the semiconductor element and another electrode of the semiconductor element. The wire shape measurement method includes: an image capturing step of respectively capturing two-dimensional images of the semiconductor device with a plurality of cameras; a three-dimensional image generation step of generating a three-dimensional image of the wire from the two-dimensional images of the semiconductor device acquired by the cameras by pattern matching using connection position information of a position where the wire is connected to the substrate or the semiconductor element and thickness information of the wire; and a measurement step of measuring a shape of the wire based on the three-dimensional image of the wire generated.

Further, the wire shape measurement method according to the present invention may include an inspection step of inspecting the shape of the wire based on the three-dimensional image of the wire generated, and the inspection step may inspect the shape of the wire by comparing the three-dimensional image of the wire generated with a reference shape of the wire. In addition, the inspection step may extract a shape parameter of the wire from the three-dimensional image of the wire generated, and inspect the shape of the wire by comparing the shape parameter extracted with a reference value of the shape parameter.

Thereby, it is possible to perform various shape measurements and shape inspections on the wire.

### Effects

The present invention can provide a wire shape measurement device that is capable of measuring a shape of a wire with high accuracy in a short time.

### BRIEF DESCRIPTION OF THE DRAWINGS

FIG. 1 is an elevational view showing the wire shape measurement device according to the embodiment.

FIG. 2 is a plan view showing the wire shape measurement device according to the embodiment.

FIG. 3 is a flowchart showing an operation of the wire shape measurement device according to the embodiment.

FIG. 4 is a perspective view showing an arrangement of a wire and cameras of the wire shape measurement device according to the embodiment.

FIG. 5 is an explanatory view showing a two-dimensional image acquired by imaging a wire with a camera arranged on the Y-direction plus side of the semiconductor device of the wire shape measurement device according to the embodiment.

FIG. 6 is an explanatory view showing a two-dimensional image acquired by imaging a wire with a camera arranged on the Y-direction minus side of the semiconductor device of the wire shape measurement device according to the embodiment.

### DESCRIPTION OF THE EMBODIMENTS

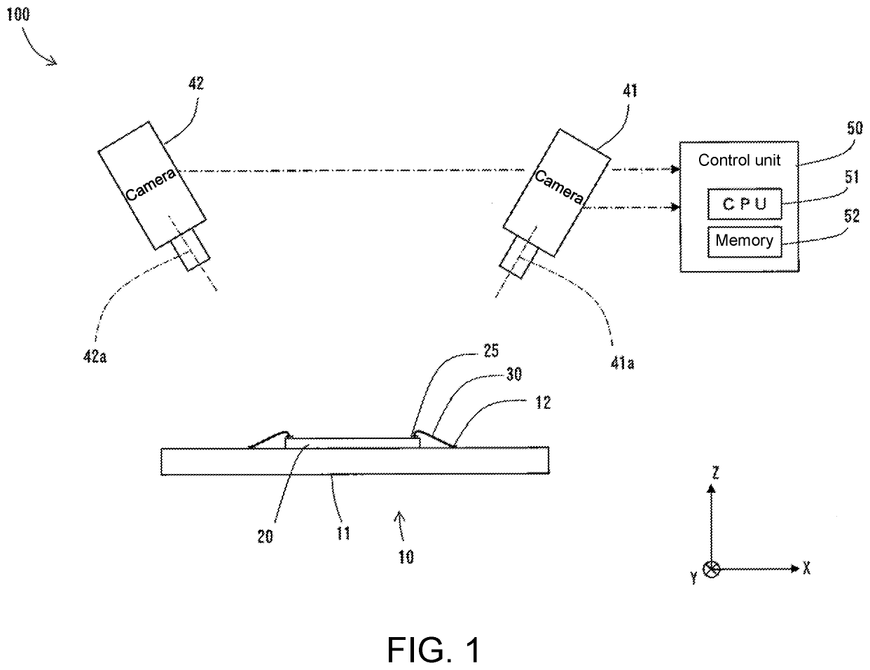

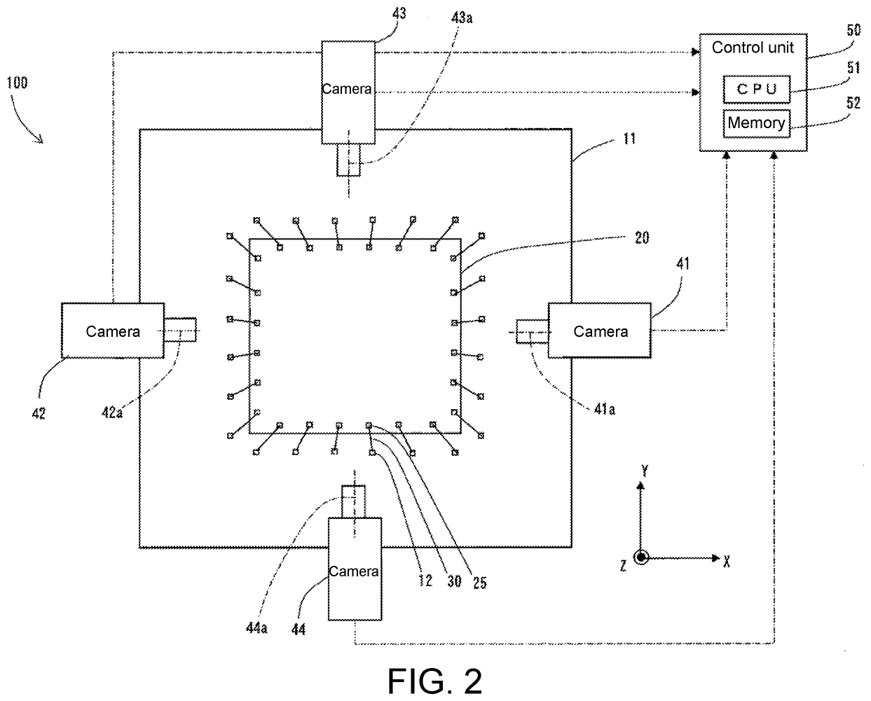

Hereinafter, a wire shape measurement device 100 according to an embodiment will be described with reference to the drawings. As shown in FIG. 1 and FIG. 2, the wire shape measurement device 100 is a device for measuring the shape of a wire 30 of a semiconductor device 10, which includes a substrate 11, a semiconductor element 20 mounted on the substrate 11, and the wire 30 connecting an electrode 25 of the semiconductor element 20 and an electrode 12 of the substrate 11. The wire shape measurement device 100 includes a plurality of cameras 41 to 44 that capture two-dimensional images of the semiconductor device 10, and a control unit 50 that inspects the shape of the wire 30 based on the two-dimensional images acquired by the cameras 41 to 44. In the following description, an X direction and a Y direction are orthogonal to each other in a horizontal plane, and a Z direction is a vertical direction.

As shown in FIG. 2, the cameras 41 and 42 are arranged so that the optical axes 41a and 42a extend in the X direction, and are arranged so as to image the semiconductor device 10 from diagonally above in the X direction. Further, the cameras 43 and 44 are arranged so that the optical axes 43a and 44a extend in the Y direction, and are arranged so as to image the semiconductor device 10 from diagonally above in the Y direction. Therefore, the cameras 41 and 42 are arranged on both sides of the wire 30 extending in the Y direction so that the optical axes 41a and 42a intersect the wire 30 extending in the Y direction, and the cameras 43 and 44 are arranged on both sides of the wire 30 extending in the X direction so that the optical axes 43a and 44a intersect the wire 30 extending in the X direction. Each of the cameras 41 to 44 is connected to the control unit 50, and data of the image acquired by each camera is input to the control unit 50. The control unit 50 is a computer including a CPU 51 that processes information internally, and a memory 52 that stores data, programs, etc.

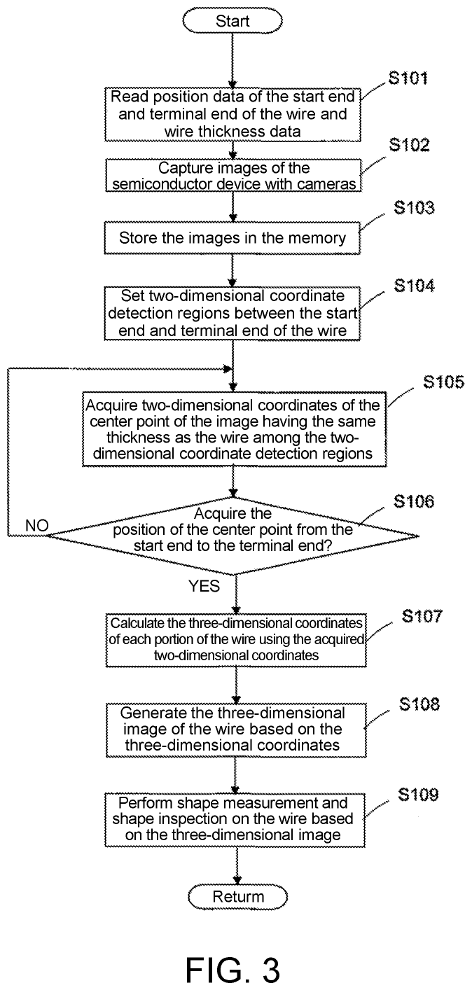

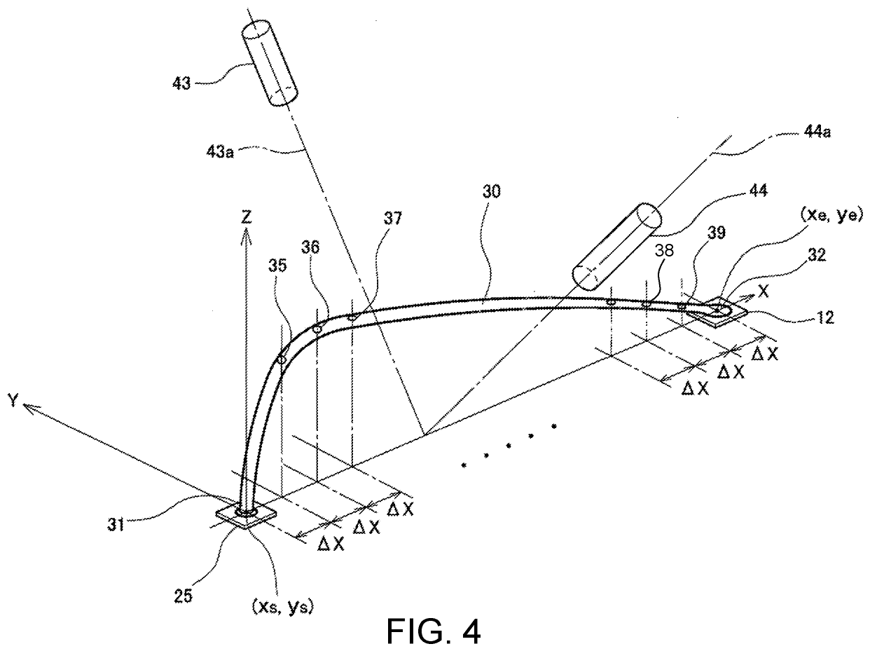

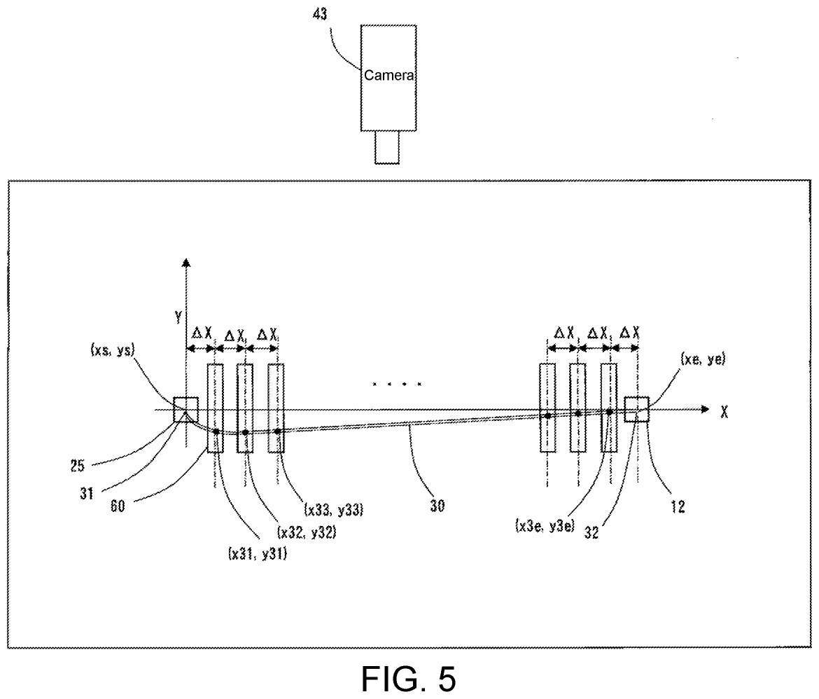

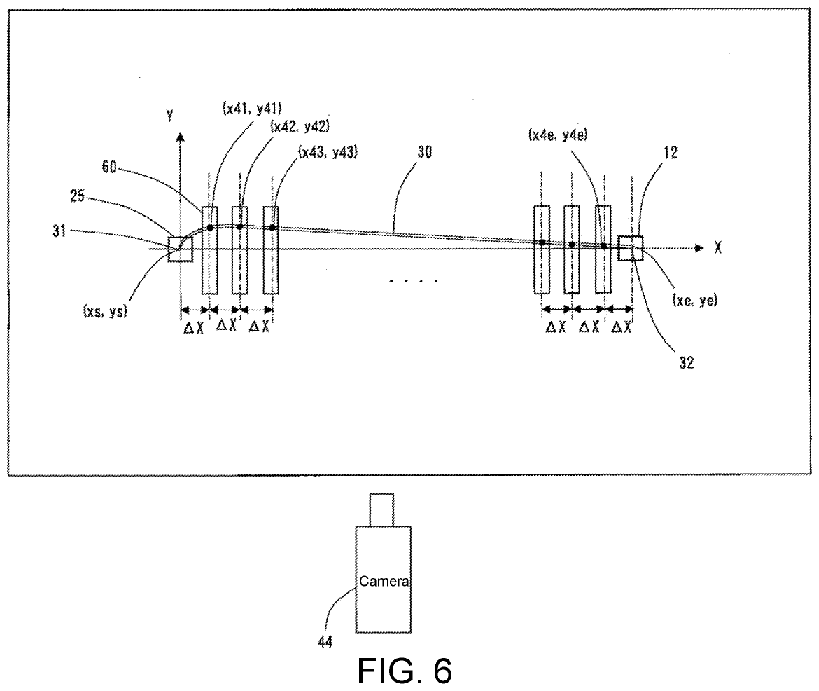

Next, an operation of the wire shape measurement device 100 according to the embodiment will be described with reference to FIG. 3 to FIG. 6. In the following description, as shown in FIG. 4, a three-dimensional image of the wire 30 which extends in the X direction between the electrode 25 of the semiconductor element 20 and the electrode 12 of the substrate 11 is generated based on a two-dimensional image captured by the camera 43 arranged diagonally above the wire 30 on the Y-direction plus side and a two-dimensional image captured by the camera 44 arranged diagonally above the wire 30 on the Y-direction minus side, and the shape of the wire 30 extending in the X direction is inspected by using the generated three-dimensional image. In FIG. 4, reference numerals 35 to 37 and 39 indicate portions of the wire 30 located in two-dimensional coordinate detection regions 60 (described later with reference to FIG. 5 and FIG. 6) for detecting two-dimensional coordinates of the wire 30, which are set at predetermined intervals AX in the middle of an X-axis that connects a start end 31 and a terminal end 32 of the wire 30.

As shown in step S101 of FIG. 3, the CPU 51 of the control unit 50 reads the coordinates (xs, ys), (xe, ye) of the start end 31 of the wire 30 connected to the electrode 25 of the semiconductor element 20 and the terminal end 32 connected to the electrode 12 of the substrate 11 from the memory 52. Here, the coordinates are connection position information of a position where the wire 30 is connected to the semiconductor element 20. Further, the CPU 51 of the control unit 50 reads a diameter of the wire 30 which is thickness information of the wire 30 from the memory 52.

Next, as shown in step S102 of FIG. 3, the control unit 50 captures images of the semiconductor device 10 with the cameras 43 and 44, and as shown in step S103 of FIG. 3, stores the captured images in the memory 52.

When the wire 30 is imaged by the camera 43 arranged on the Y-direction plus side of the semiconductor device 10, as shown in FIG. 5, the two-dimensional image of the wire 30 acquired by the camera 43 is an image curved toward the Y-direction minus side according to the change in the height of the wire 30. Further, when the wire 30 is imaged by the camera 44 arranged on the Y-direction minus side of the semiconductor device 10, as shown in FIG. 6, the two-dimensional image of the wire 30 acquired by the camera 44 is an image curved toward the Y-direction plus side according to the change in the height of the wire 30.

Next, as shown in step S104 of FIG. 3 and FIG. 5, the control unit 50 sets the two-dimensional coordinate detection regions 60 for detecting the two-dimensional coordinates of the wire 30 at the predetermined intervals AX in the middle of the X-axis that connects the start end 31 and the terminal end 32 of the wire 30 in the image acquired by the camera 43. Then, as shown in step S105 of FIG. 3, the control unit 50 searches the two-dimensional coordinate detection regions 60 for a linear image having a thickness the same as the diameter of the wire 30 by using pattern matching. Then, when the control unit 50 detects an image having a thickness the same as the diameter of the wire 30, the control unit 50 acquires the two-dimensional coordinates of the center point of the image as (x31, y31), (x32, y32), (x33, y33) and stores them in the memory 52. The two-dimensional coordinates (x31, y31), (x32, y32), (x33, y33) are two-dimensional coordinates corresponding to the portions 35 to 36 of the wire 30 shown in FIG. 4. Then, the control unit 50 repeats the operation of acquiring the two-dimensional coordinates from the start end 31 to the terminal end 32, and acquires the two-dimensional coordinates (x31, y31) to (x3e, y3e) of the center point of the image having a thickness the same as the diameter of the wire 30 in all the two-dimensional coordinate detection regions 60 from the start end 31 to the terminal end 32. These two-dimensional coordinates are two-dimensional coordinates corresponding to the portions 35 to 39 of the wire 30, respectively.

Similarly, as shown in FIG. 6, the control unit 50 sets the two-dimensional coordinate detection regions 60 in the image acquired by the camera 44, and searches the two-dimensional coordinate detection regions 60 for a linear image having a thickness the same as the diameter of the wire 30 by using pattern matching. Then, when the control unit 50 detects an image having a thickness the same as the diameter of the wire 30, the control unit 50 acquires the two-dimensional coordinates of the center point of the image as (x41, y41) to (x4e, y4e) and stores them in the memory 52. These two-dimensional coordinates are two-dimensional coordinates corresponding to the portions 35 to 39 of the wire 30, respectively. Then, when the control unit 50 determines YES in step S106 of FIG. 3, the control unit 50 proceeds to step S107 of FIG. 3.

Since the two-dimensional coordinates (x31, y31) acquired from the image of the camera 43 and the two-dimensional coordinates (x41, y41) acquired from the image of the camera 44 in step S105 of FIG. 3 are two-dimensional coordinates corresponding to the same portion 35 of the wire 30 shown in FIG. 4, three-dimensional coordinates of the portion 35 of the wire 30 can be calculated from the two two-dimensional coordinates and the positions of the cameras 43 and 44. Similarly, since the two-dimensional coordinates (x32, y32) and (x33, y33) acquired from the image of the camera 43 and the two-dimensional coordinates (x42, y42) and (x43, y43) acquired from the image of the camera 44 are two-dimensional coordinates corresponding to the same portions 36 and 37 of the wire 30 shown in FIG. 4, three-dimensional coordinates of the portions 36 and 37 of the wire 30 can be calculated from these coordinates.

Therefore, in step S107 of FIG. 3, the control unit 50 calculates the three-dimensional coordinates of a plurality of portions 35 to 39 from the start end 31 to the terminal end 32 of the wire 30 shown in FIG. 4 based on the two-dimensional coordinates (x31, y31) to (x3e, y3e) from the start end 31 to the terminal end 32 of the wire 30 acquired by the camera 43, the two-dimensional coordinates (x41, y41) to (x4e, y4e) from the start end 31 to the terminal end 32 of the wire 30 acquired by the camera 44, and the positions of the cameras 43 and 44.

Then, in step S108 of FIG. 3, the control unit 50 connects the three-dimensional coordinates of the plurality of portions 35 to 39 calculated to generate a three-dimensional image of the wire 30. Therefore, the three-dimensional image of the wire 30 is a curve that is bent three-dimensionally.

In step S109 of FIG. 3, the control unit 50 measures the dimensions of the shape of the wire 30 based on the generated three-dimensional image of the wire 30. Further, the control unit 50 compares the generated three-dimensional image of the wire 30 with a reference shape such as a reference loop shape of the wire 30 to detect the difference between the two dimensions, and determines that the shape of the wire 30 is abnormal if the difference exceeds a predetermined threshold value.

In addition, the control unit 50 may also measure the shape parameters of the wire 30 from the generated three-dimensional image of the wire 30, for example, the shape dimensions such as the loop height which is the height from the start end 31 of the wire 30, the thickness of the crimp ball formed at the start end 31, the diameter of the crimp ball, etc., and compare each measured shape dimension with a reference value to perform the inspection.

As described above, since the wire shape measurement device 100 can generate the three-dimensional image of the wire 30 from the two-dimensional images of the semiconductor device 10 acquired by the cameras 43 and 44 by pattern matching using the two-dimensional coordinates (xs, ys) and (xe, ye) of the start end 31 and the terminal end 32 of the wire 30 and the diameter of the wire 30, the three-dimensional image can be generated accurately in a short time. Thus, it is possible to perform shape measurement and shape inspection on the wire 30 with high accuracy in a short time.

After inspection of the shape of the wire 30 extending in the Y direction, shape measurement and shape inspection are performed by performing the same processing based on the two-dimensional images captured by the cameras 41 and 42.

Furthermore, the two-dimensional images acquired by the four cameras 41 to 44, instead of the two cameras 41 and 42 or the two cameras 43 and 44, may be processed to generate the three-dimensional image of the wire 30. In addition, the two-dimensional images of four or more cameras may be processed to generate the three-dimensional image of the wire 30.

The above-described embodiment illustrates that the wire 30 for shape measurement or shape inspection connects the electrode 25 of the semiconductor element 20 and the electrode 12 of the substrate 11, but the present invention is not limited thereto. For example, the present invention can also be applied to the inspection of the shape of the wire 30 that continuously connects the electrode 25 of the semiconductor element 20 of each layer, the electrode 25 of the semiconductor element 20 of the lowermost layer, and the electrode 12 of the substrate 11 in the semiconductor device 10 which laminates a plurality of semiconductor elements 20 on the substrate 11. In such a case, the wire 30 connects one electrode 25 of the semiconductor element 20 of one layer and another electrode 25 of the semiconductor element 20 of another layer, and connects the electrode 25 of the semiconductor element 20 of the lowermost layer and the electrode 12 of the substrate 11.

Further, when a wire shape measurement method is executed using the wire shape measurement device 100 according to the embodiment, capturing the two-dimensional images of the semiconductor device 10 with the cameras and storing them in the memory 52, as shown in steps S102 and S103 shown in FIG. 3, corresponds to an image capturing step. Further, generating the three-dimensional image of the wire 30 from the captured two-dimensional images, as shown in steps S104 to S108 of FIG. 3, constitutes a three-dimensional image generation step, and measuring the shape of the wire 30 based on the three-dimensional image, as shown in step S109 of FIG. 3, constitutes a measurement step. In addition, inspecting the shape of the wire 30 based on the three-dimensional image, as shown in step S109 of FIG. 3, constitutes an inspection step.

Further, the step of extracting the two-dimensional coordinates, as in steps S104 to S106 of FIG. 3, constitutes a two-dimensional coordinate extraction step; the step of calculating the three-dimensional coordinates based on the extracted two-dimensional coordinates, as shown in step S107 of FIG. 3, constitutes a three-dimensional coordinate calculation step; and the step of generating the three-dimensional image of the wire 30 from the calculated three-dimensional coordinates, as shown in step S108 of FIG. 3, constitutes an image generation step.

Further, when a wire three-dimensional image generation method is executed using the wire shape measurement device 100 according to the embodiment, capturing the two-dimensional images of the semiconductor device 10 with the cameras and storing them in the memory 52, as shown in steps S102 and S103 of FIG. 3, corresponds to the image capturing step. In addition, generating the three-dimensional image of the wire 30 from the captured two-dimensional images, as shown in steps S104 to S108 of FIG. 3, constitutes the three-dimensional image generation step.

### DESCRIPTIONS OF REFERENCE NUMERALS

10 semiconductor device; 11 substrate; 12, 25 electrode; 20 semiconductor element; 30 wire; 31 start end; 32 terminal end; 41 to 44 camera; 41a to 44a optical axis; 50 control unit; 51 CPU; 52 memory; 60 two-dimensional coordinate detection region; 100 wire shape measurement device.

1. A wire shape measurement device for a semiconductor device, which comprises:
a substrate;
a semiconductor element mounted on the substrate; and
a wire connecting an electrode of the semiconductor element and an electrode of the substrate, or connecting one electrode of the semiconductor element and another electrode of the semiconductor element, the wire shape measurement device comprising:
a plurality of cameras capturing two-dimensional images of the semiconductor device; and
a control unit measuring a shape of the wire based on the two-dimensional images of the semiconductor device acquired by the cameras, wherein the control unit:
respectively captures the two-dimensional images of the semiconductor device with the plurality of cameras,
sets two-dimensional coordinate detection regions at predetermined intervals in a region that connects a start point and a terminal point of connection of the wire with the substrate or the semiconductor element in each of the two-dimensional images, searches the two-dimensional coordinate detection regions for a linear image corresponding to a diameter of the wire by pattern matching that superimposes a reference pattern and a detected image, repeats a plurality of times an operation of taking a center position of the linear image corresponding to the diameter of the wire as two-dimensional coordinates of the wire in the two-dimensional coordinate detection region, and respectively extracts two-dimensional coordinates corresponding to a portion of the wire from the two-dimensional images of the semiconductor device acquired by the cameras,
calculates respective three-dimensional coordinates of a plurality of portions of the wire based on the two-dimensional coordinates respectively extracted and a position of each of the cameras,
generates a three-dimensional image of the wire based on the three-dimensional coordinates calculated, and
measures the shape of the wire based on the three-dimensional image of the wire generated.

2. (canceled)

3. (canceled)

4. The wire shape measurement device according to claim 1, wherein the cameras are respectively arranged on both sides of the wire so that optical axes of the cameras intersect a direction in which the wire extends.

5. The wire shape measurement device according to claim 1, wherein the control unit inspects the shape of the wire based on the three-dimensional image of the wire generated.

6. The wire shape measurement device according to claim 5, wherein the control unit inspects the shape of the wire by comparing the three-dimensional image of the wire generated with a reference shape of the wire.

7. The wire shape measurement device according to claim 6, wherein the control unit:
extracts a shape parameter of the wire from the three-dimensional image of the wire generated, and
inspects the shape of the wire by comparing the shape parameter extracted with a reference value of the shape parameter.

8. A wire three-dimensional image generation method for a semiconductor device, which comprises:
a substrate;
a semiconductor element mounted on the substrate; and
a wire connecting an electrode of the semiconductor element and an electrode of the substrate, or connecting one electrode of the semiconductor element and another electrode of the semiconductor element,
the wire three-dimensional image generation method comprising:
an image capturing step of respectively capturing two-dimensional images of the semiconductor device with a plurality of cameras;
a two-dimensional coordinate extraction step of setting two-dimensional coordinate detection regions at predetermined intervals in a region that connects a start point and a terminal point of connection of the wire with the substrate or the semiconductor element in each of the two-dimensional images, searching the two-dimensional coordinate detection regions for a linear image corresponding to a diameter of the wire by pattern matching that superimposes a reference pattern and a detected image, repeating a plurality of times an operation of taking a center position of the linear image corresponding to the diameter of the wire as two-dimensional coordinates of the wire in the two-dimensional coordinate detection region, and respectively extracting two-dimensional coordinates corresponding to a portion of the wire from the two-dimensional images of the semiconductor device acquired by the cameras;
a three-dimensional coordinate calculation step of calculating respective three-dimensional coordinates of a plurality of portions of the wire based on the two-dimensional coordinates respectively extracted and a position of each of the cameras; and
a three-dimensional image generation step of generating a three-dimensional image of the wire based on the three-dimensional coordinates calculated.

9. (canceled)

10. (canceled)

11. A wire shape measurement method for a semiconductor device, which comprises:
a substrate;
a semiconductor element mounted on the substrate; and
a wire connecting an electrode of the semiconductor element and an electrode of the substrate, or connecting one electrode of the semiconductor element and another electrode of the semiconductor element,
the wire shape measurement method comprising:
an image capturing step of respectively capturing two-dimensional images of the semiconductor device with a plurality of cameras;
a two-dimensional coordinate extraction step of setting two-dimensional coordinate detection regions at predetermined intervals in a region that connects a start point and a terminal point of connection of the wire with the substrate or the semiconductor element in each of the two-dimensional images, searching the two-dimensional coordinate detection regions for a linear image corresponding to a diameter of the wire by pattern matching that superimposes a reference pattern and a detected image, repeating a plurality of times an operation of taking a center position of the linear image corresponding to the diameter of the wire as two-dimensional coordinates of the wire in the two-dimensional coordinate detection region, and respectively extracting two-dimensional coordinates corresponding to a portion of the wire from the two-dimensional images of the semiconductor device acquired by the cameras;
a three-dimensional coordinate calculation step of calculating respective three-dimensional coordinates of a plurality of portions of the wire based on the two-dimensional coordinates respectively extracted and a position of each of the cameras;
a three-dimensional image generation step of generating a three-dimensional image of the wire based on the three-dimensional coordinates calculated; and
a measurement step of measuring a shape of the wire based on the three-dimensional image of the wire generated.

12. The wire shape measurement method according to claim 11, comprising an inspection step of inspecting the shape of the wire based on the three-dimensional image of the wire generated.

13. The wire shape measurement method according to claim 12, wherein the inspection step inspects the shape of the wire by comparing the three-dimensional image of the wire generated with a reference shape of the wire.

14. The wire shape measurement method according to claim 13, wherein the inspection step extracts a shape parameter of the wire from the three-dimensional image of the wire generated, and inspects the shape of the wire by comparing the shape parameter extracted with a reference value of the shape parameter.
